(19) United States
(12) Patent Application Publication
(10) Pub. No.: US 2019/0215615 A1
(43) Pub. Date: Jul. 11, 2019

(54) MEMS microphone

(71) Applicant: AAC Acoustic Technologies (Shenzhen) Co., Ltd., Shenzhen (CN)

(72) Inventors: Jinyu Zhang, Shenzhen (CN); Rui Zhang, Shenzhen (CN)

(21) Appl. No.: 16/236,390

(22) Filed: Dec. 29, 2018

(30) Foreign Application Priority Data
Jan. 8, 2018 (CN) 201820030475.9

(51) Int. Cl. H04R 19/04; B81B 3/00

(52) U.S. Cl. CPC H04R 19/04; B81B 3/0072; H04R 2201/003; B81B 2201/0257; B81B 2203/0127

(57) ABSTRACT

The present disclosure provides a MEMS microphone including a base having an acoustic cavity and a capacitor structure fixed to the base; the capacitor structure includes a backplate and a diaphragm that is arranged oppositely to and spaced apart from the backplate, the backplate has a balance hole penetrating therethrough, the diaphragm has a via hole penetrating therethrough, and at least a part of an orthographic projection of the via hole towards the backplate is outside the balance hole. Compared with the related art, the MEMS microphone of the present disclosure has better reliability.

### TECHNICAL FIELD

The present application claims priority to Chinese Application No. 201820030475.9, filed on Jan. 8, 2018, the content of which is incorporated herein by reference in its entirety.

### TECHNICAL FIELD

The present disclosure relates to the acoustic and electrical field and, in particular to a MEMS microphone used in portable electronic products.

### BACKGROUND

With the development of communication technology, there are more and more mobile phone users around the world. The demand for mobile phones by users does not only lie in conversation, but also in providing high-quality conversation effects. Especially with the development of mobile multimedia technology, the conversation quality of the mobile phones becomes more important. A microphone of the mobile phone serves as a voice pickup device of the mobile phone, and the design quality of the microphone directly affects the conversation quality.

A microphone in the related art, in particular a MEMS microphone, includes a base having an acoustic cavity, a backplate fixed to the base, a fixed electrode attached to the backplate, and a diaphragm that is fixed to the base and arranged opposite to and spaced apart from the backplate to form a capacitor structure. The diaphragm is provided with a via hole penetrating therethrough, and the backplate is provided with a balance hole penetrating therethrough.

However, in the MEMS microphone of the related art, the via hole and the balance hole directly face each other, and when the diaphragm is impacted by an external airflow, it is easily broken due to insufficient strength, thereby adversely affecting the reliability of the MEMS microphone.

Therefore, it is necessary to provide a new MEMS microphone to solve the above technical problems.

### BRIEF DESCRIPTION OF DRAWINGS

In order to illustrate the technical solutions in the embodiments of the present disclosure more clearly, the drawings used in the description of the embodiments will be briefly described below. It is to be understood that the drawings in the following description are only some embodiments of the present disclosure, and those skilled in the art can obtain other drawings according to these drawings without any creative effort, wherein:

FIG. 1 is a perspective structural schematic diagram of a MEMS microphone of the present disclosure;

FIG. 2 is a first structural schematic diagram of the MEMS microphone of the present disclosure, with a diaphragm having a via hole and a backplate having a balance hole;

FIG. 3 is a second structural schematic diagram of the MEMS microphone of the present disclosure, with a diaphragm having a via hole and a backplate having a balance hole;

FIG. 4 is a third structural schematic diagram of the MEMS microphone of the present disclosure, with a diaphragm having a via hole and a backplate having a balance hole;

FIG. 5 is a fourth structural schematic diagram of the MEMS microphone of the present disclosure, with a diaphragm having a via hole and a backplate having a balance hole.

### DESCRIPTION OF EMBODIMENTS

The technical solutions in the embodiments of the present disclosure will be clearly and completely described in conjunction with the accompany drawings in the embodiments of the present disclosure. It is to be understood that the described embodiments are only part of the embodiments of the present disclosure, but not all of the embodiments. All other embodiments obtained by those skilled in the art based on the embodiments of the present disclosure without creative efforts are within the protection scope of the present disclosure.

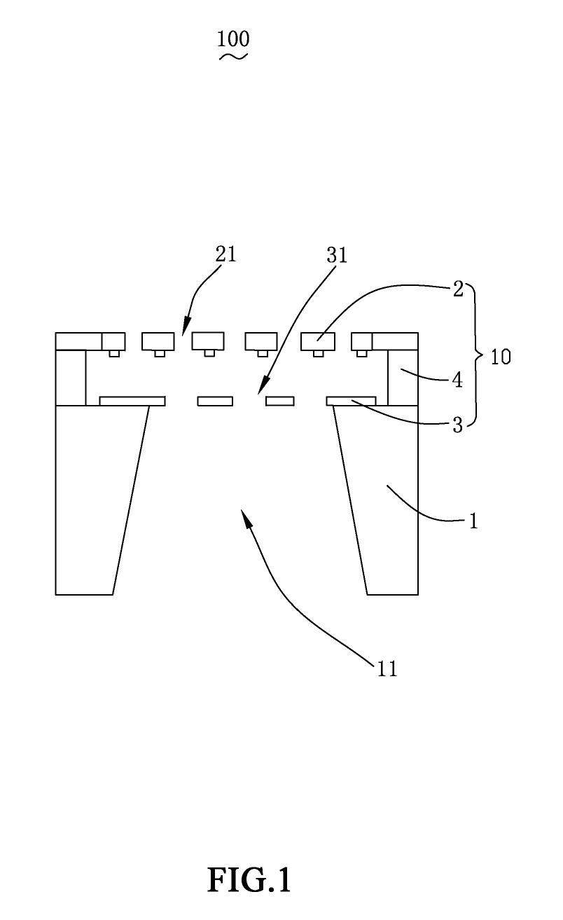

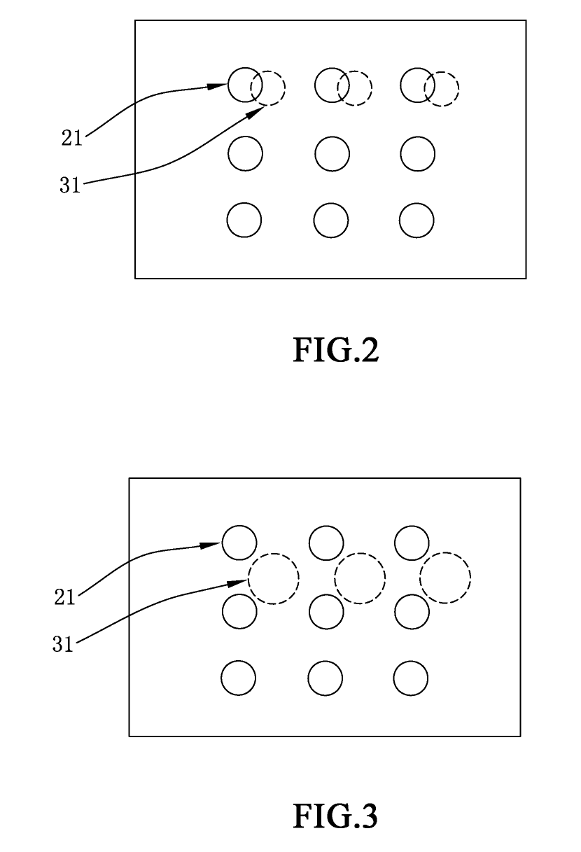

Referring to FIGS. 1-2, an embodiment of the present disclosure provides a MEMS microphone 100 including a base 1 and a capacitor structure 10 fixed to the base 1.

The base 1 has an acoustic cavity 11 penetrating therethrough, and the base 1 is formed by a MEMS process with a silicon-based material.

The capacitor structure 10 includes a backplate 2, a diaphragm 3 that is arranged opposite to and spaced apart from the backplate 2, and a supporting portion 4 located between the backplate 2 and the diaphragm 3. The diaphragm 3 is driven to vibrate by sound pressure in such a manner that a relative distance between the diaphragm 3 and the backplate 2 changes, thereby changing a capacitance of the capacitor structure formed by the diaphragm 3 and the backplate 2, then converting the capacitance into different electrical signals and realizing acoustoelectric conversion.

The diaphragm 3 is fixed to the base 1. The diaphragm 3 is provided with a through via hole 31 that penetrates through the diaphragm 3 and is used for reducing an internal stress of the diaphragm 3 and improving sensitivity of its vibration.

The backplate 2 is fixed to the base 1 by the supporting portion 4, and the supporting portion 4 is located beyond the diaphragm 3. The backplate 2 is provided with a through balance hole 21 that penetrates through the backplate 2 and is used for balancing pressure.

In other embodiments, the positions of the diaphragm and the backplate are also interchangeable, that is, the backplate is fixedly connected to the base, while the diaphragm is located on a side of the backplate facing away from the base and is connected to the base by the supporting portion.

In the present embodiment, at least a part of an orthographic projection of the via hole 31 towards the backplate 2 is outside the balance hole 21. That is, the orthographic projection of the via hole 31 and the balance hole 21 do not completely overlap. When the diaphragm 3 is impacted by an airflow, the airflow forms a high-pressure region in a non-overlapping region after entering into a gap cavity between the backplate 2 and the diaphragm 3 due to the configuration that the via hole 31 and the balance hole 21 do not completely overlap, thereby making it possible to cancel an impact force acting on the diaphragm 3. It is equivalent to an increase of strength of the diaphragm 3, and therefore, the risk of the diaphragm 3 being impacted and ruptured by the airflow is avoided and the reliability of the MEMS microphone 100 is improved.

The configuration that at least a part of the orthographic projection of the via hole 31 towards the backplate 2 is outside the balance hole 21 can be achieved in various manners, such as by setting up relative position, hole size, and quantities of the via holes 31 and the balance holes 21, and so on.

For example, in one embodiment, the diaphragm 2 have a plurality of via holes 31, the backplate 2 has a plurality of balance holes 21, and orthographic projections of the plurality of via holes 31 towards the backplate 2 and the plurality of balance holes 21 are arranged in a staggered manner. That is, the balance holes 21 and the orthographic projections of the via holes 31 do not overlap at all.

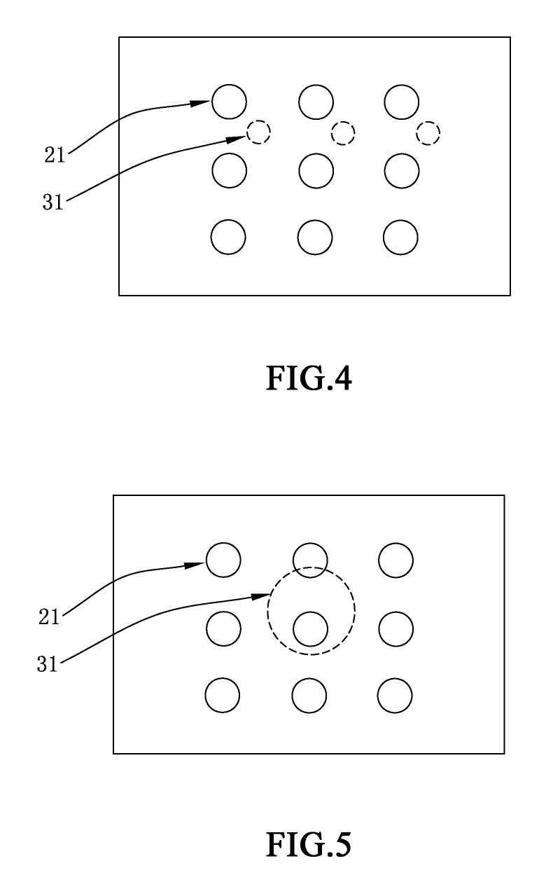

As shown in FIGS. 3-4, optionally, when the orthographic projections of the via holes 31 towards the backplate 2 and the balance holes 21 are arranged in a staggered manner, an area of a single via hole 31 can be different from an area of a single balance hole 21. For example, the area of a single via hole 31 is larger than the area of a single balance hole 21; alternatively, the area of a single via hole 31 is smaller than the area of a single balance hole 21. All of the above configurations are feasible.

In another embodiment, as shown in FIG. 5, the backplate 2 has a plurality of balance holes 21 that is spaced apart from one another, while the diaphragm 3 has one via hole 31 and the orthographic projection of the via hole 31 towards the backplate 2 covers only a portion of the balance holes 21. At this time, a part of the orthographic projection of the via hole 31 towards the backplate 2 falls into the region between the balance holes 21 of the backplate 2.

It is also feasible to reverse the number and position of the balance hole 21 and the number and position of the through hole 31 in the above-described embodiments, and the principle is the same.

Compared with the related art, the MEMS microphone of the present disclosure is configured in a manner that at least a part of the orthographic projection of the via hole towards the backplate is outside the balance hole of the backplate, i.e., the orthographic projection of the via hole and the balance hole do not completely overlap. When the diaphragm is impacted by an airflow, the airflow forms a high-pressure region in an non-overlapping region after entering into a gap cavity between the backplate and the diaphragm due to the configuration that the orthographic projection of the via hole and the balance hole do not completely overlap, thereby making it possible to cancel an impact force acting on the diaphragm, which is equivalent to an increase of the strength of the diaphragm, and therefore, the risk of being impacted and ruptured by the airflow is avoided and the reliability of the MEMS microphone is improved.

The above are only the embodiments of the present disclosure, and it should be noted that those skilled in the art can make improvements without departing from the concept of the present disclosure, but all of the improvements shall fall into the protection scope of the disclosure.

What is claimed is:

1. A MEMS microphone, comprising:
a base having an acoustic cavity, and
a capacitor structure fixed to the base, wherein the capacitor structure comprises a backplate and a diaphragm that is arranged oppositely to the backplate and is spaced apart from the backplate, the backplate has a balance hole that penetrates through the backplate, and the diaphragm has a via hole that penetrates through the diaphragm,
wherein at least a part of an orthographic projection of the via hole towards the backplate is outside the balance hole.

2. The MEMS microphone as described in claim 1, wherein the diaphragm has a plurality of via holes, the backplate has a plurality of balance holes, and orthographic projections of the plurality of via holes towards the backplate and the plurality of balance holes are arranged in a staggered manner.

3. The MEMS microphone as described in claim 2, wherein an area of a single via hole of the plurality of via holes is different from an area of a single balance hole of the plurality of balance holes.

4. The MEMS microphone as described in claim 1, wherein the backplate has a plurality of balance holes, the plurality of balance holes is spaced apart from one another, and the diaphragm has one via hole and an orthographic projection of the one via hole towards the backplate covers only a portion of the plurality of balance holes.

5. The MEMS microphone as described in claim 1, wherein the diaphragm is fixed to the base and the backplate is located on a side of the diaphragm facing away from the base.

6. The MEMS microphone as described in claim 5, wherein the capacitor structure further comprises a supporting portion located beyond the diaphragm, and the backplate is connected to the base by the supporting portion.

7. The MEMS microphone as described in claim 1, wherein the backplate is connected to the base and the diaphragm is located on a side of the backplate facing away from the base.

8. The MEMS microphone as described in claim 7, wherein the capacitor structure further comprises a supporting portion located beyond the diaphragm, and the diaphragm is connected to the base by the supporting portion.
